(19) United States
(12) Patent Application Publication
(10) Pub. No.: US 2024/0364366 A1
(43) Pub. Date: Oct. 31, 2024

(54) Wireless Circuitry having Power Control Loop with Interference Suppression Filter

(71) Applicant: Apple Inc., Cupertino, CA (US)

(72) Inventor: Andrea Camuffo, Munich (DE)

(21) Appl. No.: 18/308,492

(22) Filed: Apr. 27, 2023

(51) Int. Cl. H04B 1/00; H03F 3/24

(52) U.S. Cl. CPC H04B 1/0053; H03F 3/245; H03F 2200/451

(57) ABSTRACT

Wireless circuitry may include at least first and second transmit paths coupled to one or more antennas via a radio-frequency coupler. The radio-frequency coupler can receive via switching and filter circuitry a first radio-frequency signal from the first transmit path and a second radio-frequency signal from the second transmit path. The radio-frequency coupler can be coupled to an automatic power control (APC) loop for dynamically adjusting a signal power level of the first radio-frequency signal. The APC loop can include a feedback receiver and a power control circuit having first and second inputs. A first digital filter can be coupled at the first input of the power control circuit and can be configured to reject the second radio-frequency signal. A second digital filter matching the first digital filter can be coupled at the second input of the power control circuit and can be configured to filter a reference baseband signal.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. Signals to be transmitted by a power amplifier can be controlled using a power control loop. If care is not taken, unwanted interference can leak into the power control loop and can cause the power control loop to regulate the transmitted signals to wrong power levels.

### SUMMARY

An electronic device may include wireless communications circuitry. The wireless communications circuitry can include one or more processors or signal processing blocks for generating baseband signals, a transceiver for receiving the digital signals and for generating corresponding radio-frequency signals, and one or more radio-frequency amplifiers configured to amplify the radio-frequency signals for transmission by one or more antennas in the electronic device.

An aspect of the disclosure provides wireless circuitry that includes a first transceiver, a second transceiver, a radio-frequency front end module having inputs coupled to the first transceiver and the second transceiver, and a control loop configured to dynamically adjust the first transceiver based on signals output from the radio-frequency front end module. The control loop can include a filter circuit configured to reject signals associated with the second transceiver. The first transceiver can include a multiplier circuit configured to receive a baseband signal and a radio-frequency converter block configured to receive a scaled signal from the multiplier circuit. The radio-frequency front end module can include a radio-frequency amplifier configured to receive a radio-frequency signal from the radio-frequency converter block and switching and filter circuitry configured to receive an amplified signal from the radio-frequency amplifier and to receive an additional radio-frequency signal from the second transceiver. The wireless circuitry can include a radio-frequency coupler that is coupled between the radio-frequency front end module and an antenna. The control loop can include a feedback receiver configured to receive a feedback signal from the radio-frequency coupler and a power control circuit having an input coupled to the feedback receiver via the filter circuit and having an output coupled to the multiplier circuit. The power control circuit can have an additional input configured to receive the baseband signal via a reference path. The wireless circuitry can include an additional filter circuit coupled to the additional input of the power control circuit and configured to filter the baseband signal.

An aspect of the disclosure provides a method that includes using a radio-frequency coupler that is coupled to an antenna to receive a first radio-frequency signal from a first transceiver and to receive a second radio-frequency signal from a second transceiver, using the radio-frequency coupler to couple at least a portion of the first radio-frequency signal and at least a portion of the second radio-frequency signal onto a feedback path, using a feedback receiver to receive the portion of the first radio-frequency signal and the portion of the second radio-frequency signal via the feedback path and outputting a demodulated feedback signal, and using a filter to filter the demodulated feedback signal to reject the portion of the second radio-frequency signal. The method can further include using a digital multiplier in the first transceiver to scale the first radio-frequency signal and using a power controller to receive a filtered signal from the filter and to dynamically adjust the digital multiplier based on the filtered signal. The method can further include using the first transceiver to receive a baseband signal, using an additional filter to filter the baseband signal, and using the power controller to receive an additional filtered signal from the additional filter and to dynamically adjust the digital multiplier based on the filtered signal and the additional filtered signal.

An aspect of the disclosure provides circuitry that includes a radio-frequency amplifier, switching and filter circuitry coupled to an output of the radio-frequency amplifier and configured to receive a first radio-frequency signal in a first frequency band and to receive a second radio-frequency signal in a second frequency band different than the first frequency band, a feedback receiver configured to receive a portion of the first radio-frequency signal and a portion of the second radio-frequency signal, and a digital filter configured to reject the portion of the second radio-frequency signal while passing the portion of the first radio-frequency signal. The circuitry can further include a power control circuit configured to adjust the first radio-frequency signal based on a filtered signal output from the digital filter and an additional digital filter having an identical structure as the digital filter. The digital filter can be coupled at a first input of the power control circuit. The additional digital filter can be coupled at a second input of the power control circuit.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry in accordance with some embodiments.

FIG. 3 is a diagram of illustrative wireless transmission circuitry having an automatic power control (APC) loop in accordance with some embodiments.

FIG. 4 is a diagram showing a power spectrum of a signal of interest and nearby an interference signal in accordance with some embodiments.

FIG. 5 is a diagram of illustrative wireless transmission circuitry having an automatic power control (APC) loop having matching filters in accordance with some embodiments.

### DETAILED DESCRIPTION

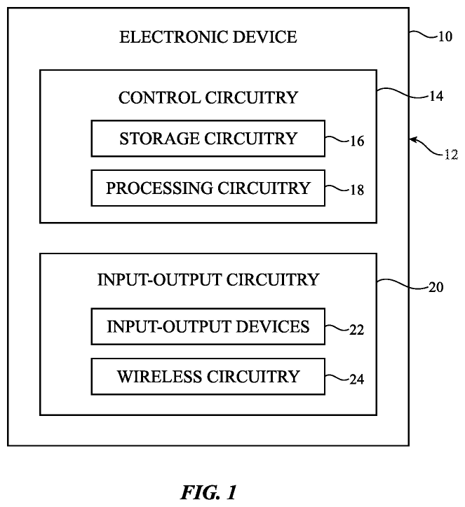

An electronic device such as device 10 of FIG. 1 may be provided with wireless circuitry. The wireless circuitry can include radio-frequency (RF) amplifiers such as radio-frequency power amplifiers. A radio-frequency transmit path can include a radio-frequency power amplifier coupled to an antenna via a radio-frequency coupler. The radio-frequency power amplifier can receive a transmit signal having a power level that is controlled by an automatic power control (APC) circuit. The automatic power control circuit can receive a feedback signal via a feedback receiver that is coupled to the radio-frequency coupler. The feedback receiver and the automatic power control circuit can be considered to be part of a closed-loop power control mechanism for the transmit path.

The radio-frequency power amplifier can be used to amplify radio-frequency signals in cellular telephone frequency bands, sometimes referred to as cellular signals. In accordance with some embodiments, switching and filtering circuitry coupled between an output of the radio-frequency power amplifier and the radio-frequency coupler can receive radio-frequency signals associated with other radio access technologies such as wireless local area network (WLAN) signals, Bluetooth (BT) signals, and/or other potentially interference, aggressor, or blocker signals. In such configurations, the feedback signals received at the automatic power control circuit can include cellular signals and any signals such as for example WLAN/BT signals that might interfere with the cellular signals.

The automatic power control circuit can have a first input configured to receive a reference transmit signal and can have a second input configured to receive a feedback signal from the radio-frequency coupler. A digital filter can be coupled at the second input of the automatic power control circuit to filter out the interfering WLAN/BT signals. An additional digital filter can optionally be coupled at the first input of the automatic power control circuit to precondition (predistort) the reference transmit signal in the same way as the filtered feedback signal arriving at the first input of the automatic power control circuit. Configured and operated in this way, the digital filter can suppress unwanted signals so that the automatic power control circuit can properly adjust the transmit signals to correct signal levels under a variety of operating conditions.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHZ WLAN band (e.g., from 2400 to 2480 MHZ), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHz Bluetooth® band or other WPAN communications bands, cellular telephone frequency bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHZ), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

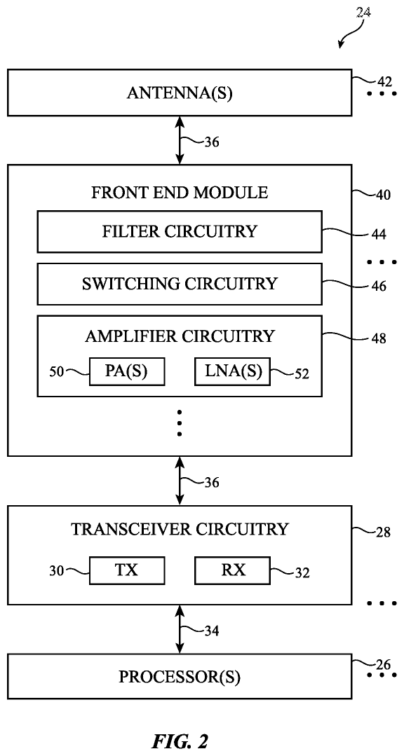

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to 4G (LTE) transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 36, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

Front end module (FEM) 40 may include radio-frequency front end circuitry that operates on the radio-frequency signals conveyed (transmitted and/or received) over radio-frequency transmission line path 36. Front end module 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHZ WLAN band (e.g., from 5180 to 5825 MHz), a Wi-Fi® 6E band (e.g., from 5925-7125 MHZ), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHZ, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PA) circuits 50 in the transmit (uplink) path. A power amplifier 50 (sometimes referred to as radio-frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

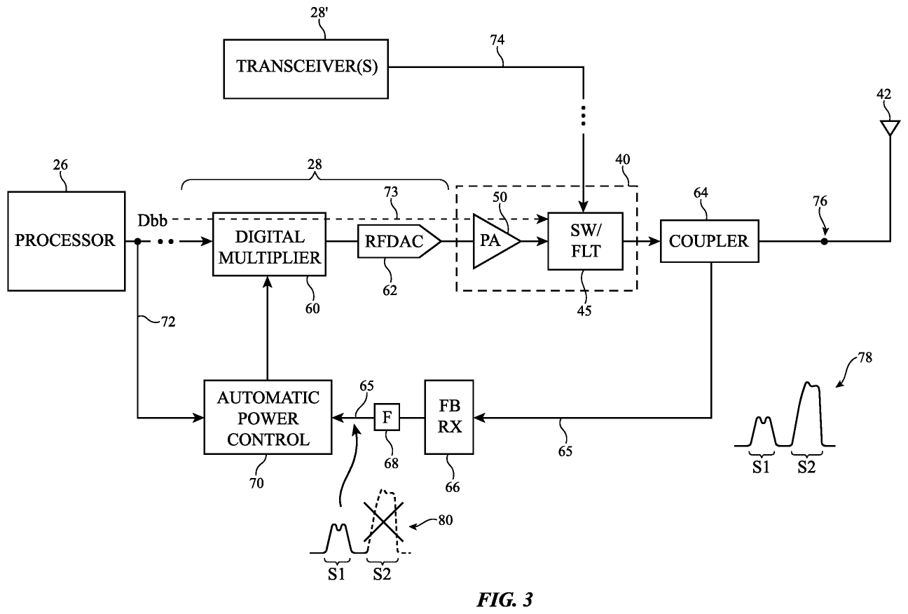

FIG. 3 is a diagram of illustrative wireless circuitry 24 having a power control loop. As shown in FIG. 3, wireless circuitry 24 may include processor 26, a digital multiplier circuit such as digital multiplier 60, a radio-frequency converter block such as radio-frequency converter block 62, a radio-frequency power amplifier such as radio-frequency amplifier 50, front end circuitry such as switch and filter circuitry 45, a radio-frequency coupling circuit such as radio-frequency coupler 64, and an antenna 42 configured to radiate radio-frequency signals for transmission to an external device. Processor 26 may represent one or more processors such as a baseband processor, an application processor, a digital signal processor, a microcontroller, a microprocessor, a central processing unit (CPU), a programmable device, a combination of these circuits, and/or one or more processors within circuitry 18. Processor 26 may be configured to generate a digital baseband signal Dbb. Signal Dbb is sometimes referred to as a digital signal, a baseband signal, or a transmit signal. As examples, signal Dbb generated by processor 26 may include in-phase (I) and quadrature-phase (Q) signals, radius and phase signals, a vector input, or other digitally coded signals.

Digital multiplier 60 may have an input configured to receive digital baseband signal Dbb from processor 26, a control input configured to receive a control signal from a control circuit such as automatic power control (APC) circuit 70, and an output on which a corresponding scaled signal is generated. Digital multiplier 60 may be configured to multiply or scale the received signal Dbb by a multiplier (scaling) factor that is a function of the control signal output from the automatic power controller 70. The control signal output from automatic power controller 70 may be referred to as an automatic power control (APC) adjustment signal. For example, dynamically adjusting the APC adjustment signal in a first direction can increase the scaling factor provided by the digital multiplier 60 to boost the power level of the scaled signal output from digital multiplier 60. Conversely, dynamically adjusting the APC adjustment signal in a second direction opposing the first direction can decrease the scaling factor provided by the digital multiplier 60 to reduce the power level of the scaled signal output from digital multiplier 60. The scaled signal generated at the output of digital multiplier 60 can also sometimes be referred to as a power-adjusted digital signal.

Radio-frequency converter block 62 may be configured to convert the scaled signal output from the digital multiplier 60 from the digital domain to the analog domain (to generate analog signals) and then to upconvert or modulate the analog signals to radio frequencies. The term “radio-frequency converter” may thus refer to or be defined herein as a circuit that can perform both signal domain conversion (e.g., digital to analog conversion) and frequency upconversion (e.g., from baseband frequencies to radio frequencies or intermediate frequencies). Baseband frequencies can range from a couple hundred Hz to a couple hundred MHz. The input of radio-frequency amplifier 50 configured to receive radio-frequency signals can be referred to or defined herein as a radio-frequency input (port). Radio frequencies can range from hundreds of MHz to tens of GHz. RF converter block 62 may output a radio-frequency signal to the radio-frequency input port of amplifier 50. Radio-frequency amplifier 50 may generate a corresponding amplified radio-frequency signal.

The example described above in which converter block 62 performs digital-to-analog (D/A) conversion before conducting frequency upconversion in the analog domain is illustrative.

In another embodiment, RF converter block 62 can perform frequency upconversion in the digital domain before performing digital-to-analog conversion. In general, RF converter block 62 may include a plurality of N individual digital-to-analog converters, each of which is sometimes referred to or defined herein as a radio-frequency DAC (“RFDAC”) or RFDAC cell (e.g., converter block 62 can include N separate radio-frequency DACs). Digital multiplier 60 and RF converter block 62 are sometimes referred to as being part of a transceiver 28.

The output of radio-frequency amplifier 50 may be coupled to switch and filter circuitry 45. Switch and filter circuitry 45 may include filter circuitry 44 of the type described in connection with FIG. 2 and/or switching circuitry 46 of the type described in connection with FIG. 2. Radio-frequency amplifier 50 and switch and filter circuitry 45 are sometimes considered part of a front end module (see dotted box 40 in FIG. 3). Switching and filter circuitry 45 can have one or more input terminals configured to receive signals from a variety of different transceivers. In the example of FIG. 3, switching and filter circuitry 45 can have a first input configured to receive first radio-frequency signals from radio-frequency amplifier 50 and a second input (or a second set of inputs) configured to receive second radio-frequency signals from one or more separate transceiver(s) 28′ via path 74.

The first radio-frequency signals can be signals in cellular telephone frequency bands (e.g., bands from about 600 MHZ to about 5 GHZ, 3G bands, 4G LTE bands, 5G New Radio FR1 bands below 10 GHZ, 5G New Radio FR2 bands between 20 and 60 GHZ, etc.), sometimes referred to as cellular signals. The second radio-frequency signals can be signals in WLAN frequency bands (e.g., Wi-Fi® (IEEE 802.11) or other WLAN communications bands such as a 2.4 GHZ WLAN band (e.g., from 2400 to 2480 MHZ), a 5 GHZ WLAN band (e.g., from 5180 to 5825 MHZ), a Wi-Fi® 6E band (e.g., from 5925-7125 MHZ), and/or other Wi-Fi® bands (e.g., from 1875-5160 MHZ). Such radio-frequency signals in WLAN frequency bands can sometimes be referred to herein as WLAN signals. As another example, the second radio-frequency signals can be signals in wireless personal area network (WPAN) frequency bands such as the 2.4 GHZ Bluetooth® (BT) band or other WPAN communications bands, sometimes referred to herein as BT signals. In general, the first radio-frequency signals (e.g., cellular signals) and the second radio-frequency signals (e.g., WLAN and/or BT signals) can be signals generated using different radio access technologies (RATs). In FIG. 3, transceiver(s) 28′ can include a WLAN transceiver, a BT transceiver, and/or other types of wireless transceivers.

As examples, the different radio access technologies can include Global System for Mobile Communications (GSM), Code Division Multiple Access (CDMA), Universal Mobile Telecommunications System (UTMS), 4G (LTE), 5G, Wi-Fi®, Bluetooth®, Zigbee, Near Field Communication (NFC), Radio Frequency Identification (RFID), Narrowband-Internet of Things (NB-IoT), just to name a few. In general, switching and filter circuitry 45 can be configured to receive incoming signals from only one radio access technology via one transmit path, from two or more radio access technologies via at least two separate transmit paths, from three or more radio access technologies via at least three separate transmit paths, from four or more radio access technologies via at least four separate transmit paths, from five or more radio access technologies via at least five separate transmit paths, from five to ten radio access technologies, or from more than ten radio access technologies. Each of the separate transmit paths can optionally have its own closed-loop power control mechanism. The switching and filter circuitry 45 can combine the radio-frequency signals generated using the various radio access technologies and output the combined radio-frequency signals to antenna 42 via radio-frequency coupler 64. Radio-frequency coupler 64 may be coupled between switching and filter circuitry 45 and antenna 42. Radio-frequency coupler 64 can be configured to couple or convey at least a portion of the combined radio-frequency signals output from switching and filter circuitry 45 to a feedback receiver circuit such as feedback receiver 66. Radio-frequency coupler 64 may be coupled to feedback receiver 66 via a feedback path 65.

Conventionally, the WLAN/BT signals are transmitted using a separate antenna from the cellular signals. Given size and space constraints and the growing number of frequency bands and radio technologies that need to be included in modern mobile devices, however, antenna sharing among transceivers associated with different radio access technologies is becoming more common. In accordance with some antenna sharing schemes, the WLAN/BT signals can be injected into the transmit path using a diplexer that can be disposed at a location 76 between the RF coupler and the antenna. Injecting the WLAN/BT signals using a diplexer at location 76 after the RF coupler ensures the WLAN/BT signals do not disturb the radio-frequency signals coupled onto the feedback path 65. In accordance with the embodiment of FIG. 3, however, the signals associated with the other radio access technologies can be injected through the switching and filter circuitry 45 before the radio-frequency coupler 64 via path 74 (e.g., a diplexer can be omitted at location 76). In other words, there is no diplexer between coupler 64 and antenna 42 in FIG. 3. Connecting the one or more transceivers 28′ to the front end module 40 before the RF coupler 64 in this way may be technically advantageous and beneficial by providing a component layout simplification (which reduces cost) while minimizing an insertion loss that would otherwise have been introduced by a diplexer at location 76.

Coupling multiple transceivers to switching and filter circuitry 45 prior to RF coupler 64, however, can cause signals from multiple frequency bands to be coupled onto the feedback path 65. The feedback signal on feedback path 65 may have a power spectral density as shown by power spectrum 78. In the example of FIG. 3, power spectrum 78 may include a first radio-frequency signal S1 that is generated based on digital baseband signal Dbb output from processor 26 and amplified by power amplifier 50 (e.g., signal S1 can be generated using a first radio access technology) and a second radio-frequency signal S2 that is generated by transceiver(s) 28′ via path 74 (e.g., signal S2 can be generated using one or more second radio access technology that is different than the first radio access technology). Signal S1 is generated from a first transmit path 73, whereas signal S2 is generated from a second transmit path 74. As an example, signal S1 might represent a cellular signal of interest, whereas signal S2 might represent WLAN and/or BT signals in a nearby frequency band. The frequency bands of signals S1 and S2 can be separated by 1-10 MHZ, by less than 10 MHz, by less than 1 MHZ, by tens of MHz, by hundreds of MHz, etc. Feedback receiver 66 can be configured to receive this feedback signal (e.g., an analog signal) that includes radio-frequency signals S1 and S2. Feedback receiver 66 can include a downconversion (demodulation) circuit and a data conversion circuit such as an analog-to-digital converter (ADC) for downconverting or demodulating the feedback signal from radio-frequencies to a baseband frequency and for converting the feedback signal from the analog domain to the digital domain. Configured in this way, feedback receiver 66 can generate a corresponding demodulated digital feedback signal at its output.

Automatic power controller 70 can have a first input coupled to the output of the feedback receiver 66, a second input configured to receive digital baseband signal Dbb from processor 26 via path 72, and an output coupled to the control input of digital multiplier 60. Path 72 is sometimes referred to herein as a reference path. Signal Dbb that is provided to the second input of automatic power controller 70 is sometimes referred to and defined herein as a reference signal. Automatic power controller 70 may be configured to compare a power level of the demodulated digital feedback signal with a power level of the reference signal Dbb to generate a corresponding control signal for adjusting a gain or scaling (multiplication) factor that is provided by digital multiplier 60. Such mechanism for adjusting the gain or power level of the transmit signal is sometimes referred to as a closed-loop power control architecture. This closed-loop power control scheme can ensure a proper signal level or quality at antenna 42 even under harsh or extreme environmental conditions (e.g., automatic power controller 70 can be used to dynamically regulate the transmit power level to ensure optimal performance under extreme temperatures or even when the voltage standing wave ratio (VSWR) is abnormally high).

In the example of FIG. 3, however, the presence of signal S2 nearby signal S1 can interfere with the performance or efficacy of the power control loop that is regulating transmit path 73. The another transmit path 74 can optionally have its own automatic power control loop (not shown). The frequency bands of signals S1 and S2 can be separated by less than 1 MHZ, by less than 10 MHz, by tens of MHz, by hundreds of MHZ, etc. Signal S2 is generated by a separate transceiver 28′, which runs independently of digital multiplier 60, so the power control loop for controlling signal S1 should not be affected by the signal contribution from S2. Signal S2 is thus sometimes referred to and defined herein as an interference signal or an aggressor signal, whereas signal S1 is sometimes referred to and defined herein as a signal of interest. In accordance with an embodiment, a filter circuit such as digital filter 68 can be interposed between feedback receiver 66 and the first input of automatic power controller 70. Digital filter 68 can be a low pass filter, an elliptical filter, an infinite impulse response (IIR), or other types of filtering component. Digital filter 68 can be configured to filter out or reject the interference signal S2, as marked by signal rejection 80. Operated in this way, digital filter 68 can suppress the unwanted aggressor signals S2, which allows the automatic power controller 70 precisely regulate transmit signals S1 to the desired power levels. Filter 68 is therefore sometimes referred to as an interference suppression filter. This approach can also be applied to inter-band transmit carrier aggregation architectures.

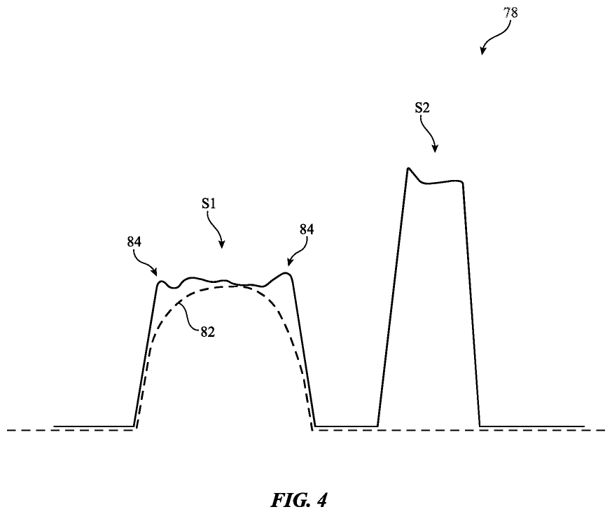

FIG. 4 is a diagram showing a magnified view of power spectrum 78 of the feedback signal. As shown in FIG. 4, the feedback signal can include a signal of interest S1 and a nearby aggressor signal S2 that can potentially interfere with signal S1. Digital filter 68 (see FIG. 3) can provide a sharp filter response as indicated by dotted line 82 to reject aggressor signal S2. Such sharp filter (cut-off) response 82 can, however, introduce some inadvertent roll-off at the edges of the filter band (as shown by roll-off portions 84). These roll-off portions 84 can cut out some of the intended signal of interest S1. Since the performance of automatic power controller 70 depends on an accurate comparison of the feedback signal received at its first input with the reference signal received at its second input, it would be important to mimic such roll-off behavior for the reference signal as well to avoid discrepancies that could lead to significant power errors.

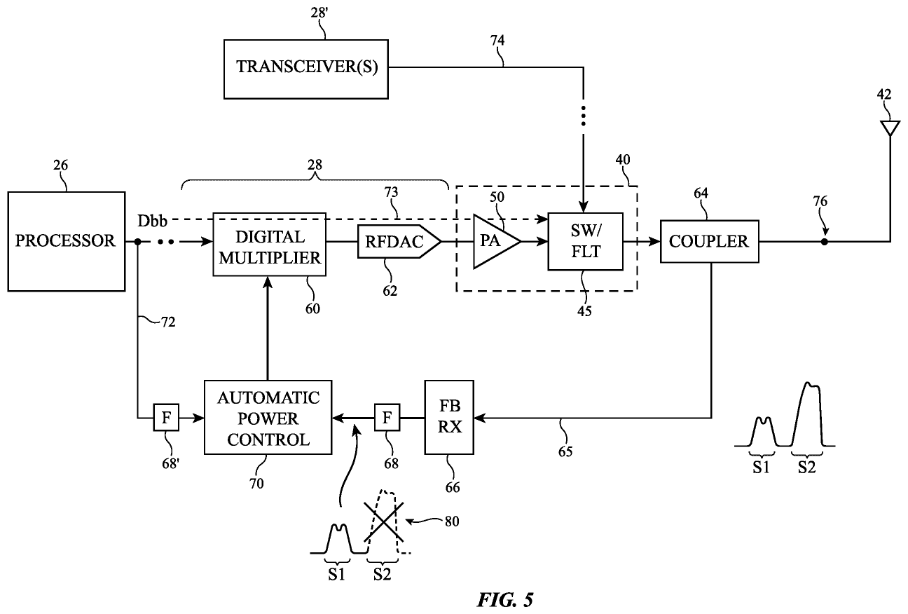

FIG. 5 shows another embodiment in which the automatic power control loop is provided with matching filters. As shown in FIG. 5, a first digital filter 68 can be coupled at the first input of automatic power controller 70, whereas a second digital filter 68′ can be coupled at the second input of automatic power controller 70. The first digital filter 68 and the second digital filter 68′ can be physically identical (e.g., filters 68 and 68′ are separate filters having identical physical structures and identical filter response). By including the same matching filter 68′ in the reference path 72, digital filter 68′ can precondition the reference signal so that the reference signal is predistorted in the same way as the feedback signal as the feedback signal traverses filter 68. Configured and operated in this way, any discrepancies or errors associated with the operation of the automatic power control loop is minimized. The remaining portion of FIG. 5 includes similar structure and function as those already described in connection with FIG. 3 and need not be reiterated in detail to avoid obscuring the present embodiment.

The embodiments of FIGS. 3 and 5 in which one or more filters (e.g., digital filter 68 and filter 68′) are included in the power control loop in a transmit architecture where a plurality of transceivers 28 and 28′ share an antenna 42 are exemplary. This technique of using filter 68 (and associated filter 68′) to reject potentially interfering signals can also be extended to non-shared antenna architectures where transceivers 28 and 28′ transmit radio-frequency signals via separate antennas. In such configurations, use of filter 68 in the power control loop can still be beneficial when the amount of isolation between the separate antennas is low.

The methods and operations described above in connection with FIGS. 1-5 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is exemplary and various modifications can be made to the described embodiments. The foregoing embodiments may be implemented individually or in any combination.

What is claimed is:

1. Wireless circuitry comprising:
a first transceiver;
a second transceiver;
a radio-frequency front end module having inputs coupled to the first transceiver and the second transceiver; and
a control loop configured to dynamically adjust the first transceiver based on signals output from the radio-frequency front end module, the control loop having a filter circuit.

2. The wireless circuitry of claim 1, wherein the filter circuit is configured to reject signals associated with the second transceiver.

3. The wireless circuitry of claim 1, wherein the first transceiver comprises:
a multiplier circuit configured to receive a baseband signal; and
a radio-frequency converter block configured to receive a scaled signal from the multiplier circuit.

4. The wireless circuitry of claim 3, wherein the radio-frequency front end module comprises:
a radio-frequency amplifier configured to receive a radio-frequency signal from the radio-frequency converter block; and
switching and filter circuitry configured to receive an amplified signal from the radio-frequency amplifier and to receive an additional radio-frequency signal from the second transceiver.

5. The wireless circuitry of claim 3, further comprising:
a radio-frequency coupler that is coupled between the radio-frequency front end module and an antenna.

6. The wireless circuitry of claim 5, wherein the control loop comprises:
a feedback receiver configured to receive a feedback signal from the radio-frequency coupler; and
a power control circuit having an input coupled to the feedback receiver via the filter circuit and having an output coupled to the multiplier circuit.

7. The wireless circuitry of claim 6, wherein the feedback receiver comprises a downconversion circuit and an analog-to-digital converter.

8. The wireless circuitry of claim 6, wherein the power control circuit has an additional input configured to receive the baseband signal via a reference path.

9. The wireless circuitry of claim 8, further comprising:
an additional filter circuit coupled to the additional input of the power control circuit and configured to filter the baseband signal.

10. The wireless circuitry of claim 9, wherein the filter circuit and the additional filter circuit are physically identical.

11. The wireless circuitry of claim 1, wherein the filter circuit comprises a low pass filter.

12. The wireless circuitry of claim 1, wherein:
the first transceiver is configured to output a first radio-frequency signal associated with a first radio access technology; and
the second transceiver is configured to output a second radio-frequency signal associated with a second radio access technology different than the first radio access technology.

13. The wireless circuitry of claim 12, wherein the first radio-frequency signal comprises a cellular signal, and wherein the second radio-frequency signal comprises a wireless local area network (WLAN) signal or a Bluetooth signal.

14. A method of operating wireless circuitry comprising:
with a radio-frequency coupler that is coupled to an antenna, receiving a first radio-frequency signal from a first transceiver and receiving a second radio-frequency signal from a second transceiver;
with the radio-frequency coupler, coupling at least a portion of the first radio-frequency signal and at least a portion of the second radio-frequency signal onto a feedback path;
with a feedback receiver, receiving the portion of the first radio-frequency signal and the portion of the second radio-frequency signal via the feedback path and outputting a demodulated feedback signal; and
with a filter, filtering the demodulated feedback signal to reject the portion of the second radio-frequency signal.

15. The method of claim 14, further comprising:
with a digital multiplier in the first transceiver, scaling the first radio-frequency signal; and
with a power controller, receiving a filtered signal from the filter and dynamically adjusting the digital multiplier based on the filtered signal.

16. The method of claim 15, further comprising:
with the first transceiver, receiving a baseband signal;
with an additional filter, filtering the baseband signal; and
with the power controller, receiving an additional filtered signal from the additional filter and dynamically adjusting the digital multiplier based on the filtered signal and the additional filtered signal.

17. The method of claim 16, wherein the filter and the additional filter comprise identical low pass filters.

18. Circuitry comprising:
a radio-frequency amplifier;
switching and filter circuitry coupled to an output of the radio-frequency amplifier and configured to receive a first radio-frequency signal in a first frequency band and to receive a second radio-frequency signal in a second frequency band different than the first frequency band;
a feedback receiver configured to receive a portion of the first radio-frequency signal and a portion of the second radio-frequency signal; and
a digital filter configured to reject the portion of the second radio-frequency signal while passing the portion of the first radio-frequency signal.

19. The circuitry of claim 18, further comprising:
a power control circuit configured to adjust the first radio-frequency signal based on a filtered signal output from the digital filter.

20. The circuitry of claim 19, further comprising:
an additional digital filter having an identical structure as the digital filter, wherein the digital filter is coupled at a first input of the power control circuit and wherein the additional digital filter is coupled at a second input of the power control circuit.
